(19) United States
(12) Patent Application Publication
(10) Pub. No.: US 2012/0186636 A1
(43) Pub. Date: Jul. 26, 2012

(54) FLUORINATED POLYMER AND ZINC OXIDE FILM FREE OF ANY ACRYLIC ODOR FOR PHOTOVOLTAIC USE

(75) Inventors: Anthony Bonnet, Saint Laurent de Mure (FR); Francois Beaume, Bernay (FR); Nicolas Devaux, Lyon (FR); Karine Triballier, Campbon (FR); Stephane Bizet, Barc (FR); Frederic Godefroy, Mesnll sous Jumieges (FR)

(73) Assignee: Arkema France, Colombes (FR)

(21) Appl. No.: 13/388,845

(22) PCT Filed: Aug. 4, 2010
(86) PCT No.: PCT/FR10/51652

§ 371 Date: Apr. 10, 2012

(30) Foreign Application Priority Data
Aug. 5, 2009 (FR) 0955515

(51) Int. Cl. C08L 27/12; H01L 31/02; C08K 3/22; C08K 9/00; C08L 27/20; B32B 5/00; B29C 49/00; B82Y 30/00

(52) U.S. Cl. 136/252; 428/220; 264/500; 524/432; 977/811; 977/902

(57) ABSTRACT

The present invention relates to a polymeric composition composed of a fluoropolymer and of zinc oxide (ZnO) of nanometric size which is intended for the manufacture of films transparent in the visible region and opaque to UV radiation. More particularly, in the composition according to the invention, the said filler is present in a proportion by weight of 0.1 to 10%, preferably of 0.5 to 6%, the ZnO particles have a size ranging from 25 to 40 nm, preferably from 30 to 35 nm, these particles have a surface treatment and the said composition is devoid of acrylic polymers.

The present invention relates to a composition comprising a fluoropolymer and zinc oxide of nanometric size. The invention also relates to the films manufactured from the said composition. Due to their transparency in the visible region and opaqueness to UV radiation, these films are intended in particular for use as frontsheet in a photovoltaic cell.

A photovoltaic cell is composed of a semiconductor material sandwiched between two metal electrodes, the entire assembly being protected by a frontsheet and a backsheet. The frontsheet of a photovoltaic cell should mainly protect the components of the cell from any mechanical attack. It should also prevent effects due to ageing induced in particular by UV radiation and oxygen. In order to use the sunlight as efficiently as possible, the frontsheets of a photovoltaic cell should, of course, have a high transmission in a certain spectral region, which, for example, extends from 400 to 1100 nm for a cell based on crystalline silicon.

It is known to manufacture photovoltaic cells with a frontsheet made of glass, a cheap and very widespread material which additionally exhibits a high mechanical strength. A frontsheet made of glass has, however, several disadvantages: a transmission with an upper limit of 92% in the range extending from 400 to 1100 nm, a high weight and a low impact strength, requiring particular care during the transportation, installation and use of the photovoltaic cells.

Frontsheets made of plastics overcome several of these disadvantages. This is because there exist plastics which exhibit a higher transmission than that of glass, which are lighter and which have a satisfactory impact strength.

Thus, it is known to use fluoropolymers in general and in particular PVDF (polymer of vinylidene difluoride VDF) to manufacture films intended to protect objects and materials, due to their very good resistance to bad weather, to UV radiation and to visible light, and to chemicals. These films exhibit a very good thermal stability for exterior applications subject to severe climatic conditions (rain, cold, heat) or conversion processes carried out at high temperature (>130° C.).

Monolayer films based on fluoropolymers (copolymer of ethylene and tetrafluoroethylene or ETFE; PVDF; copolymer of ethylene and propylene or FEP, and the like), sold by companies such as DuPont, Asahi Glass, Saint-Gobain and Rowland Technologies, are already used as frontsheet for photovoltaic cells.

Generally, in order to protect a polymer film from damage by UV rays, organic UV absorbers and/or inorganic fillers are incorporated therein. It is known that the addition of inorganic fillers, such as TiO₂, SiO₂, CaO, MgO, CaCO₃, Al₂O₃ and a great many others still, to a fluoropolymer, such as a vinylidene fluoride polymer or copolymer, can result in fairly serious damage with production of HF (hydrogen fluoride) when the blending is carried out in the molten state at a high temperature in order to disperse the filler. One route for processing these fillers with, for example, PVDF consists in introducing these inorganic fillers using an acrylic masterbatch. To this end, the inorganic fillers are dispersed in a methyl methacrylate polymer or copolymer (PMMA) and then this masterbatch is blended with the PVDF in the molten state. The presence of a PMMA results in disadvantages, such as a limitation on the dimensional stability of a film obtained with regard to temperature, a lower thermal stability, an odour characteristic of the acrylic during the assembling of the cells and a lower stability to UV radiation in comparison with the pure PVDF. A film comprising a tripartite fluoropolymer/acrylic polymer/inorganic filler composition is described, for example, in the document WO 2009/101343.

Organic UV absorbers are inert materials which absorb and scatter UV radiation. However, their use is limited due to their disadvantages, namely limited spectral coverage, their decomposition during ageing and their migration, accompanied by phenomenon of exudation. One solution, which consists in limiting the content of UV absorber, has, for example, been proposed by the Applicant Company in the document EP 1 382 640, which describes films transparent to visible light and opaque to UV radiation, the said films being composed of two layers, including one comprising PVDF, PMMA, an acrylic elastomer and a UV absorber. The results set out in Examples 1 to 5 show that no exudation is observed when a film with a thickness of 15 μm is kept in an oven for 7 days. However, limitation on the content of UV absorber may not be suitable for the manufacture of films intended for longer operating times, as is the case for photovoltaic cells.

It would thus be desirable to have available a composition devoid of acrylic and of organic UV absorber which makes it possible to manufacture a film exhibiting good properties of transparency in the visible region and of opaqueness to UV radiation and also good mechanical strength and good resistance to ageing.

The studies carried out by the Applicant Company have shown that it is possible to manufacture a film exhibiting these properties starting from a composition based on fluoropolymers and on an inorganic filler well dispersed in the said fluoropolymers while preventing damage to the said fluoropolymers and without addition of another constituent, such as an acrylic.

To this end and according to a first aspect, the invention relates to a polymeric composition composed of a fluoropolymer and zinc oxide (ZnO), the said filler being present in the said composition in a proportion by weight of 0.1 to 10%, preferably of 0.5 to 6%.

Advantageously, the fluoropolymer is a vinylidene difluoride homopolymer or a copolymer of vinylidene and at least one other fluoromonomer.

Characteristically, the ZnO particles incorporated in the composition have a size ranging from 25 to 40 nm, preferably from 30 to 35 nm. This particular nanometric size makes possible good dispersion of the particles in the body of the polymer without initiating damage to the latter when it is in the molten state during the compounding and conversion stages. Advantageously, the surface of the ZnO particles is rendered chemically inert by virtue of a surface treatment; this increases the compatibility with the fluoropolymer and results in a suspension being obtained which is homogeneous and stable over time. In addition, the composition according to the invention is devoid of acrylic polymers, which eliminates the risk of production of unpleasant odours during the conversion.

According to a second aspect, the invention relates to a monolayer film obtained from the abovementioned composition, the said film being opaque to UV radiation and transparent in the visible region and exhibiting a long term stability. These properties are recommended very particularly for use as frontsheets in a photovoltaic cell. The film according to the invention can, however, lend itself to use as backsheet in a photovoltaic cell.

The invention also relates to a process for the manufacture of the abovementioned composition, comprising a stage of incorporation by the molten route of the said filler in the fluoropolymer.

In addition, the invention also relates to processes for the manufacture of the film according to the invention, comprising, according to one alternative form, an extrusion-blowing stage at a flow rate of 300 kg/hour or, according to another alternative form, a flat sheet extrusion stage, the two operations being carried out at a temperature of between 220° C. and 240° C.

The invention and the advantages which it provides will be better understood in the light of the detailed description which will follow and of the appended figures, in which:

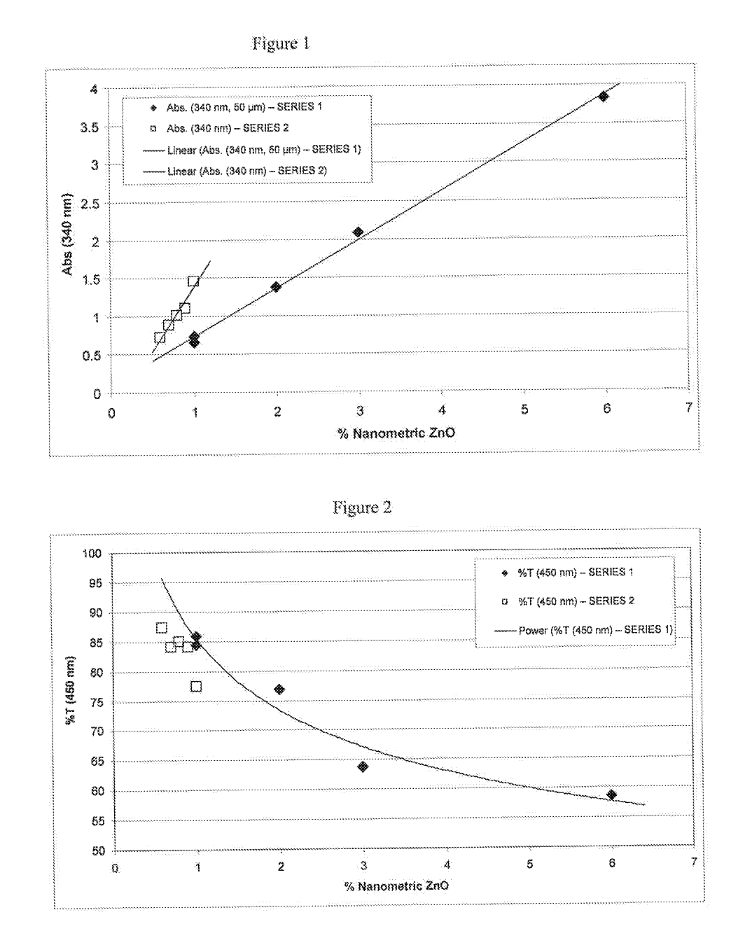

FIG. 1 is a diagram representing the variation in the absorbance at 340 nm of the film according to the invention as a function of the level by weight of ZnO in the composition;

FIG. 2 is a diagram representing the variation in the transmission at 450 nm of the film according to the invention as a function of the level by weight of ZnO in the composition.

The research studies carried out by the Applicant Company, targeted at improving the known films based on fluoropolymers which are transparent in the visible region and opaque to UV radiation, have led it to the development of compositions based on fluoropolymers comprising, as inorganic filler, ZnO particles with a particular nanometric size which, in the dispersed state and in the absence of another constituent, such as an organic UV absorber or an acrylic polymer, are capable of providing good properties of transparency in the visible region and of UV opaqueness of a film manufactured from the said composition, whether initiating damage to the said fluoropolymers during the compounding and conversion stages.

A first subject-matter of the invention is thus a polymeric composition composed of a fluoropolymer and of zinc oxide, the said filler being present in the said composition in a proportion by weight of 0.1 to 10%, preferably of 0.5 to 6%, characterized in that:

the fluoropolymer is a vinylidene difluoride homopolymer or a copolymer of vinylidene difluoride and at least one other fluoromonomer,

the ZnO particles have a size ranging from 25 to 40 nm, preferably from 30 to 35 nm,

they have a surface treatment, which renders them chemically inert,

and the said composition is devoid of acrylic polymers.

The fluoropolymer participating in the composition according to the invention is prepared by polymerization of one or more monomer(s) of formula (I):

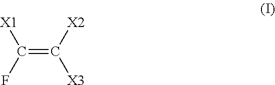

in which:

X1 denotes H or F;

X2 and X3 denote H, F, Cl, a fluoroalkyl group of formula CₙFₘHₚ— or a fluoroalkoxy group CₙFₘHₚO—, n being an integer between 1 and 10, m being an integer between 1 and (2n+1) and p having the value 2n+1−m.

Mention may be made, as examples of monomers, of hexafluoropropylene (HFP), tetrafluoroethylene (TFE), vinylidene fluoride (VDF, CH₂=CF₂), chlorotrifluoroethylene (CTFE), perfluoroalkyl vinyl ethers, such as CF₃—O—CF=CF₂, CF₃—CF₂—O—CF=CF₂ or CF₃—CF₂CF₂—O—CF=CF₂, 1-hydropentafluoropropene, 2-hydropentafluoropropene, dichlorodifluoroethylene, trifluoroethylene (VF3), 1,1-dichlorofluoroethylene and their mixtures, or fluorine-comprising diolefins, for example diolefins such as perfluorodiallyl ether and perfluoro-1,3-butadiene.

The fluoropolymer is a VDF homopolymer or copolymer.

Advantageously, the fluorocomonomer which can copolymerize with the VDF is chosen, for example, from vinyl fluoride, trifluoroethylene (VF3); chlorotrifluoroethylene (CTFE); 1,2-difluoroethylene; tetrafluoroethylene (TFE); hexafluoropropylene (HFP); perfluoro(alkyl vinyl) ethers, such as perfluoro(methyl vinyl) ether (PMVE), perfluoro(ethyl vinyl) ether (PEVE) and perfluoro(propyl vinyl) ether (PPVE); perfluoro(1,3-dioxol); perfluoro(2,2-dimethyl-1,3-dioxol) (PDD), and their mixtures.

Preferably, the fluorocomonomer is chosen from chlorotrifluoroethylene (CTFE), hexafluoropropylene (HFP), trifluoroethylene (VF3) and tetrafluoroethylene (TFE), and their mixtures. The comonomer is advantageously HFP as it copolymerizes well with VDF and makes it possible to contribute good thermomechanical properties. Preferably, the copolymer comprises only VDF and HFP.

Preferably, the fluoropolymer is a VDF homopolymer (PVDF) or a VDF copolymer, such as VDF/HFP, comprising at least 50% by weight of VDF, advantageously at least 75% by weight of VDF and preferably at least 90% by weight of VDF. Mention may be made, for example, more particularly of the following VDF homopolymers or copolymers comprising more than 75% of VDF and the remainder of HFP: Kynar® 710, Kynar® 720, Kynar® 740, Kynar Flex® 2850 and Kynar Flex® 3120, sold by Arkema.

Advantageously, the VDF homopolymer or copolymer has a viscosity ranging from 100 Pa.s to 3000 Pa.s, the viscosity being measured at 230° C. at a shear gradient of 100 s⁻¹ using a capillary rheometer. This is because this type of polymer is well suited to extrusion. Preferably, the polymer has a viscosity ranging from 500 Pa.s to 2900 Pa.s, the viscosity being measured at 230° C. at a shear gradient of 100 s⁻¹ using a capillary rheometer.

The zinc oxide participating in the composition according to the invention has an opacifying role in the UV region (185 to 400 nm) and acts as sunscreen, so that a film prepared from the composition according to the invention is a film which is opaque to UV radiation, namely by scattering/reflection of the UV rays.

The size of the particles of the filler is between 25 and 40 nm, preferably from 30to 35 nm (limits included). The content by weight of inorganic filler in the composition is between 0.1 and 10%, advantageously between 0.5 and 6% (limits included). This content and the small size of the particles ensure good properties of transparency in the visible region (400 to 700 nm) for a film manufactured from the composition according to the invention.

Advantageously, in the composition according to the invention, the ZnO particles have a surface treatment which renders the said particles chemically inert with respect to the fluoropolymers. This has the effect of preventing damage to the fluoropolymers, in particular PVDF, during the compounding and conversion stages. The term “surface treatment” of the ZnO particles is understood to mean, in the context of the invention, a chemical or physical operation which has the consequence of modifying the surface of the ZnO particles in order to render the latter chemically inert with regard to the fluoropolymer. This has the effect of preventing yellowing of the fluoropolymer.

According to one embodiment, the ZnO particles are coated with silicon-based compounds, such as silane or silane-based compounds. An example of this type is composed of the ZnO powder of the range sold under the name of Zano® 20 by Umicore.

According to a preferred embodiment, the composition according to the invention is composed of PVDF and of ZnO particles with a size ranging from 30 to 35 nm, the content by weight of the filler being from 0.5 to 6%.

The composition according to the invention can be prepared by a process comprising a stage of incorporation by the molten route of the said nanometric filler directly in the fluoropolymer in the absence of acrylic polymer. This method of preparation ensures good dispersion of nanometric ZnO particles in order to confer, on the film which is manufactured from the said composition, good opaqueness to UV radiation while retaining good transparency in the visible region. The absence of acrylic polymers in the composition ensures, on the one hand, the absence of acrylic odours during the conversion and, on the other hand, it guarantees the excellent properties of the PMMA-free PVDF in terms of long term UV stability, stability towards bad weather (weather ability), chemical resistance, resistance to certain solvents and temperature stability for the film which will be manufactured from this composition.

According to another aspect, a subject-matter of the invention is a monolayer film manufactured from the composition described above. This film is opaque to UV radiation and transparent in the visible region while retaining very good properties of dimensional stability at the temperatures used for the manufacture of a frontsheet or of a backsheet and subsequently of a photovoltaic panel. Furthermore, the film according to the invention exhibits a long-term stability and can be coated with a layer of silicon oxide or aluminium oxide in order to obtain barrier properties with regard to water and oxygen.

The film according to the invention exhibits the following characteristics:

a thickness of between 10 and 100 μm, advantageously between 15 and 90 μm, preferably between 20 and 80 μm (limits included);

a density of between 1.79 and 1.86 g/cm³ (limits included);

a weight per unit area of between 17.9 and 186 g/m² (limits included);
an elongation at break (in %):
   in the machine direction: of between 50 and 500%;
   in the cross direction: of between 50 and 500%;

a tensile strength (in MPa):
in the machine direction: of between 30 and 70 MPa;
in the cross direction: of between 20 and 60 MPa;

a dimensional modification after passing through the oven at 150° C. for 30 min (in %):
in the machine direction: <1%
in the cross direction: <1%.

Advantageously, the film according to the invention does not exhibit an acrylic odour.

The film according to the invention is manufactured, according to a first embodiment, by tubular (bubble) extrusion-blowing (blown film) at a temperature ranging from 240 to 260° C. This technique consists in coextruding, generally from the bottom upwards, a thermoplastic polymer through an annular die. The extrudate is simultaneously drawn longitudinally by a drawing device, usually in the form of rolls, and inflated with a constant volume of air trapped between the die, the drawing system and the wall of the tube. The inflated tube is generally cooled by an air blowing ring at the die outlet.

According to another embodiment, the film is manufactured by flat sheet extrusion of polymer (extrusion cast) at a temperature ranging from 240 to 260° C. In this process, the molten plastic is introduced into a flat die. At the outlet, the material is cooled on a cooling roll and subsequently drawn, so as to obtain the desired thickness. At the end of the line, the film is wound off. The flat film extrusion process makes it possible to obtain excellent optical and dimensional properties.

Advantageously, the small size of the particles of inorganic filler present in the composition used for the manufacture of the film and also the nature of these fillers make it possible to obtain the film by these extrusion techniques at temperatures of 240-260° C. without causing damage to the fluoropolymer present in the said composition. This makes it possible to retain intact the particular properties of this polymer, namely its very good resistance to bad weather, to UV radiation and to oxygen.

According to another embodiment, the film is manufactured by following the stages below:

blending on a calender nanometric ZnO in the molten fluoropolymer, at a temperature ranging from 220 to 260° C., preferably at 240° C.;

hot pressing (at a temperature of 220 to 230° C.) this blend, in order to obtain first a thicker film (for example with a thickness of 150 μm), and then pressing the latter again, to give thinner films of variable thickness, for example ranging from 20 to 80 μm.

According to another aspect, a subject-matter of the invention is the use of this film in the manufacture of the frontsheet in a photovoltaic panel. Advantages of the film according to the invention:

“permanent” visible transparency and UV opaqueness in PVDF by virtue of the nanofillers, i.e. different from organic UV absorbers (no consumption, no migration or extrudation), and thus maintenance of the performances in the long term,

makes possible a monolayer film combining transparency, chemical resistance, resistance to solvents, temperature stability and long term UV protection.

According to another aspect, a subject-matter of the invention is the use of this film in the manufacture of the backsheet in a photovoltaic panel. To this end, according to one embodiment, the film according to the invention is first subjected on both its faces, to a surface treatment of corona type. Subsequently, it is heat laminated on each side with a PET sheet coated beforehand with adhesive. One of the faces of the laminate thus obtained is subsequently pressed against a film of EVA type, the other face of the latter being adhesively bonded to a cleaned glass sheet. This laminated structure can be used as backsheet in a photovoltaic cell. Furthermore, the PET may or may not be pigmented with TiO₂ according to the wish to have, in the end, an opaque or transparent backsheet.

Other characteristics and advantages of the invention will become apparent on reading the following implementation examples.

### SERIES 1: Blending Operations on the Calender Followed by Pressing a Film

The blends S1-A, C, D, E are prepared on a two-roll calender at 240° C. by introducing from 1 to 6% of “nanometric ZnO with surface treatment” (Zano20) into molten Kynar 740. The blend S1-B is obtained by preparing, under the same conditions, a masterbatch comprising 20% of “nanometric ZnO with surface treatment” (Zano20) in Kynar 740, which masterbatch is subsequently diluted to a level of 5% in Kynar 740 in order to obtain a final composition identical to that of the blend S1-A. After cooling, all these blends appear white and devoid of bubbles. The Kynar 740 used here is a PVDF homopolymer.

They are subsequently pressed at 220-230° C. to give films with a thickness of 150 μm and are then pressed again to give thinner films of approximately 50-75 μm.

The blends S1-F and S1-G were prepared according to the same protocol as the blends S1-A and S1-B, respectively but while using “nanometric ZnO without surface treatment” and while lowering the temperature to 200° C. These two blends and the intermediate masterbatch exhibit visible signs of the beginning of decomposition of the Kynar 740: yellow/brown colouring, indeed even pronounced brown colouring for the masterbatch, and presence of fine bubbles. These characteristics indicate the beginning of decomposition of the Kynar 740 brought about by the “nanometric ZnO without surface treatment”, despite a blending temperature lowered to 200° C.

These blends will thus not be pressed or analysed in terms of optical properties.

### Optical Measurements:

The absorbance and the transmission of these films are measured on a Cary 300 spectrophotometer from Varian equipped with an integrating sphere (with an angle of 8°): the film holder is installed at the inlet of the sphere and the Spectralon is placed on the sample reflectance port. The base line is recorded with the empty film holder. The UV spectra of the films are obtained by the following parameters:

module spectra

range: 200-800 nm

rate: 12 nm/min

change in lamp: 350 nm

mode: transmission

SBW:2.0nm.

It was chosen to compare the absorbance values at 340 nm (wavelength corresponding to an absorbance minimum in the UV region for the blends with nanometric ZnO). The absorbance value measured was corrected for a theoretical film thickness of 50 μm by a rule of 3 with regard to the thickness, in order to facilitate the comparisons and since the absorbance varies linearly with the thickness.

The comparison of the transmittance is carried out at 450 nm for all the blends.

The results are shown in Table 1 below and in the appended FIGS. 1 and 2.

TABLE 1
SERIES 1: Blending operations on a calendar, followed by pressing

| | Surface | | Thickness | Abs | |
|---|---|---|---|---|---|
| | treatment on | % | of | (340 nm | % T |
| Exam- | nanometric | Nanometric | the film | 50 μm)- | (450 nm) - |
| ple | ZnO | ZnO | (μm) | SERIES 1 | SERIES 1 |
| S1-A | yes | 1 | 60 | 0.73 | 84.3 |
| S1-B | yes | 1 | 61 | 0.65 | 85.9 |
| S1-C | yes | 2 | 73 | 1.37 | 76.8 |
| S1-D | yes | 3 | 74 | 2.09 | 63.7 |
| S1-E | yes | 6 | 47 | 3.83 | 58.5 |

| | | | |
|---|---|---|---|
| S1-F | no | 1 | beginning of decomposition |
| S1-G | no | 1 | beginning of decomposition |

### SERIES 2: Blending Operations on an Extruder Followed by Extrusion of a Film

A masterbatch comprising 7.5% of “nanometric ZnO with surface treatment” (Zano20) in Kynar 1000HD (PVDF homopolymer) was prepared on a corotating twin-screw extruder (diameter 27 mm, L/D=44) under the following conditions: feeding of the charge in the molten region, set temperature of 230° C., screw speed of 250 rev/min, throughput of 20kg/h. A white and smooth rod is obtained and is subsequently granulated. The granules may exhibit a shrinkage void at the centre but are devoid of fine decomposition bubbles.

This masterbatch is subsequently incorporated in Kynar 1000HD or Kynar Flex 3120-50 by dry blending granules to respectively give the blends S2-A (in Kynar 1000HD) and S2-B to S2-F (in Kynar Flex 3120-50). The degree of incorporation of the masterbatch defines the level of “nanometric ZnO with surface treatment” (Zano 20) in the final blend, as indicated in the table below. Kynar Flex 3120-50 is a VDF-HFP copolymer.

These blends of granules are then extruded on a tubular blown film single-screw extruder (screw diameter 30 mm, L/D=25, die diameter 50 mm, gap 1.2 mm) under the following conditions: temperature 250° C., drawing rate 5.4 m/min, BUR 2.55.

The films obtained have a thickness of approximately 50 μm and are analysed in terms of absorbance and transmission in the same way as the blends of the preceding SERIES 1. The absorbance values are the values read and not corrected for a theoretical thickness of 50 μm as for SERIES 1. The results are given in Table 2 below and in the appended FIGS. 1 and 2.

TABLE 2
SERIES 2: Blending operations on extruder,
followed by extrusion of a film

| | Surface | | | | |
|---|---|---|---|---|---|
| | treatment | | | | |
| | on | % | | Abs | % T |
| Exam- | nanometric | Nanometric | kynar | (340 nm)- | (450 nm)- |
| ple | ZnO | ZnO | matrix | SERIES 2 | SERIES 2 |
| S2-A | yes | 1 | 1000HD | 1.34 | 72.2 |
| S2-B | yes | 1 | 3120-50 | 1.46 | 77.4 |
| S2-C | yes | 0.9 | 3120-50 | 1.1 | 84 |
| S2-D | yes | 0.8 | 3120-50 | 1.01 | 85 |
| S2-E | yes | 0.7 | 3120-50 | 0.88 | 84 |
| S2-F | yes | 0.6 | 3120-50 | 0.72 | 87.3 |

1. Polymeric composition comprising a fluoropolymer and zinc oxide (ZnO) particles, said ZnO being present in said composition in a by weight of 0.1 to 10%, characterized in that the fluoropolymer is a vinylidene difluoride homopolymer or a copolymer of vinylidene difluoride (VDF) and at least one other fluoromonomer, the ZnO particles have a size ranging from 25 to 40 nm, and having a surface treatment, said composition is devoid of acrylic polymers.

2. Composition according to claim 1, in which the ZnO particles are coated with silicon-based compounds.

3. Composition according to claim 1, in which the fluoropolymer is a polyvinylidene fluoride (PVDF) homopolymer.

4. Composition according to claim 1, in which the fluorocopolymer is a copolymer of VDF and at least one other fluoromonomer comprising at least 50% by weight of VDF.

5. Composition according to claim 4, in which the other fluoromonomer is hexafluoropropylene (HFP).

6. Composition according to claim 1 comprising PVDF and ZnO particles, the ZnO particles having a size ranging from 30 to 35 nm and the content by weight of the ZnO being from 0.5 to 6%.

7. Monolayer film which is opaque to UV radiation and transparent in the visible region and which exhibits a long term stability, composed of the composition according to claim 1.

8. Film according to claim 7, wherein said film has a thickness of between 10 and 100 μm.

9. Photovoltaic panel, in which the frontsheet and/or the backsheet is/are composed of the film according to claim 7.

10. (canceled)

11. (canceled)

12. Process for the preparation of the composition according to claim 1, said composition being intended for the manufacture of a film opaque to UV radiation and transparent in the visible region, the said process comprising the step of incorporating said filler in the fluoropolymer in the molten state.

13. Process for the manufacture of the monolayer film according to claim 7 comprising the step of extrusion-blowing at a temperature ranging from 240 to 260° C.

14. Process for the manufacture of the monolayer film according to claim 7 comprising the step of flat sheet extrusion at a temperature ranging from 240 to 260° C.

15. Process for the manufacture of the monolayer film according to claim 7 comprising the steps of:
blending on a calender nanometric ZnO in the molten fluoropolymer, at a temperature ranging from 220 to 260° C.;
hot pressing, at a temperature of 220 to 230° C., this blend, in order to obtain first a film with a thickness of 150 μm, and then pressing the latter again, to give films with a thickness ranging from 10 to 100 μm.

16. Composition according to claim 4, in which the fluorocopolymer is a copolymer of VDF and at least one other fluoromonomer comprising at least 75% by weight of VDF.

17. Film according to claim 8, wherein said film has a thickness of between 15 and 90 μm.

18. Film according to claim 17, wherein said film has a thickness of between 20 and 80 μm.
